(19) United States
(12) Patent Application Publication
(10) Pub. No.: US 2003/0007658 A1
(43) Pub. Date: Jan. 9, 2003

(54) Method for the operation of a hearing aid as well as a hearing aid

(76) Inventor: Wolfram Meyer, Moehrendorf (DE)

Correspondence Address: SCHIFF HARDIN & WAITE, 6600 SEARS TOWER, 233 S WACKER DR, CHICAGO, IL, 60606-6473, US

(21) Appl. No.: 10/188,190

(22) Filed: Jul. 2, 2002

(30) Foreign Application Priority Data
Jul. 3, 2001 (DE) 10132035.3

(51) Int. Cl. H03G 7/00; H04R 25/00

(52) U.S. Cl. 381/312; 381/106

(57) ABSTRACT

A method is provided for operating a hearing aid as well as a hearing aid having at least one input transducer for picking up an input signal and converting it into an electrical signal, having an A/D converter for converting the electrical signal into a digital signal, having a signal processing unit for processing the digital signal and having an output transducer that the electrical input signal be compressed before the A/D conversion based on the criterion of a compression characteristic, and that the compressed digital signal or a signal proceeding from it can be expanded after the A/D conversion based on the criterion of an expansion characteristic that is at least approximately inverse relative to the compression characteristic.

### BACKGROUND OF THE INVENTION

1. Field of the Invention

The invention is directed to a method for operating a hearing aid having at least one input transducer for picking up an input signal and converting it into an electrical signal, having an A/D converter for converting the electrical signal into a digital signal, having a signal processing unit for processing the digital signal and having an output transducer. The invention is also directed to a hearing aid for implementing the method.

2. Description of the Related Art

A/D converter are employed for converting an analog signal into a digital signal. The prior art discloses various methods with which A/D converters operate (for example, from Tietze, U., Schenk, C H, Halbleiter-Schaltungstechnik, Berlin, Heidelberg, New York, London, Paris, Tokyo, Barcelona: Springer 1990). The dynamic range (measured in dB) of an A/D converter is defined as the ratio between minimum and maximum level of the analog signal that can be converted into a digital signal with the A/D converter.

However, the power consumption of the A/D converter rises together with the required dynamic range of the A/D converter so that A/D converters that offer a great dynamic range are unsuitable for use in hearing aids. Only A/D converters with a limited dynamic range can be employed in hearing aids because of the low output voltage and the highly restricted storage capacity of the voltage source. In digital hearing aids, it is therefore necessary to undertake suitable measures in order to avoid overdriving/overloading the A/D converter. When the dynamic range of the analog input signal exceeds the dynamic range of the A/D converter, then the digital image of the analog input signal is highly distorted.

A high level compressor (HLC) precedes the A/D converter in the “Prisma” hearing aid model of Siemens Audiologische Technik GmbH. This is intended to prevent the overdrive/overload of the A/D converter and the following circuit. The HLC has a high regulating threshold level after which the regulation responds and compresses the input signal. The compression, however, results in great distortion of the digital image of the analog input signal that ultimately lead to clearly audible and disturbing distortions of the output signal. The response and decay times of the HLC are also disadvantageous, resulting in a brief-duration overdrive/overload of the A/D converter despite the HLC. Moreover, unfavorable input signals, for example successive, loud sound events between which quiescent pauses lie, result in a type of “pump effect” as a result of the regulating circuit that is likewise very unpleasant for the user.

### SUMMARY OF THE INVENTION

An object of the invention is to increase the dynamic range in a digital hearing aid and to avoid signal distortions.

This object is achieved by a method for operating a hearing aid having at least one input transducer for picking up an input signal and converting it into an electrical signal, having an A/D converter for converting the electrical signal into a digital signal, having a signal processing unit for processing the digital signal and having an output transducer. The inventive method involves:

compressing the electrical input signal before the A/D conversion based on the criterion of a compression characteristic;

an A/D conversion of the compressed signal for generating a compressed digital signal; and

expanding the compressed digital signal or a signal proceeding from it after the A/D conversion based on the criterion of an expansion characteristic that is at least approximately inverse relative to the compression characteristic.

The object is also achieved by a hearing aid for implementing the method comprising an input transducer with compressing signal transmission behavior for compressing the input signal as well as by a hearing aid for the implementation of the method comprising a compression unit for compressing the input signal before the A/D conversion.

In order to improve the dynamic range of the analog input signal that can be transmitted by the hearing aid, the invention provides that the analog input signal be compressed before the A/D conversion and be expanded following the A/D conversion. The compression or expansion takes place directly, permanently and steadily, i.e., differing from the known HLC that only engages above a specific regulating threshold of the analog input signal. In the invention, the processing of the signal level in the invention ensues continuously based on the criterion of a compression characteristic. This characteristic is preferably linear with the slope of one in the region of low signal levels and can asymptotically approach a maximum for extremely high input levels, where the transition between these extremes may proceed in a continuous manner. The compressed analog input signal is finally supplied to the A/D converter. After the A/D conversion, the digital signal passes through an expansion unit that essentially realizes a transmission characteristic that is the inverse of the compression characteristic.

The hearing aid of the invention comprises an expanded dynamic range compared to a hearing aid that provides no compression of the input signal. Furthermore, no audible distortions occur at high signal amplitudes of the input signal given a hearing aid of the invention since the compression and expansion ensue directly and continuously. Also, the compression is permanently implemented depending on the signal strength, i.e., the compressor is not only activated above a specific regulating threshold. It therefore also has no response/decay time and the above mentioned “pump effects” are thus avoided, particularly given input signals with recurring, great amplitude discontinuities.

One embodiment of the invention provides that the compression is already effected by the input transducer. When the input transducer is fashioned, for example, as an acousto-electric transducer, then this action can be implemented using a specific fashioning in the acousto-mechanical part of the transducer, for instance by using a transducer membrane differing in thickness.

Another embodiment provides an electrical circuit unit for the compression that is connected between the input transducer and the A/D converter and realizes the desired, compressed transfer function. Use of the word “connected” is defined to mean connected either directly or indirectly throughout the specification and claims.

In both of the above embodiments, the signal processing comprises a circuit unit that may realize the inverse transfer function of the compressor in view of the signal level. This circuit unit may be implemented in analog circuit technology but is preferably implemented in digital circuit technology.

A number of different possibilities are available for the circuit-oriented realization of the compressor or expander. For example, the compressor can be fashioned as an analog logarithmizer and the expander can be fashioned as a digital delogarithmizer. Any combination of analog and digital processing may be utilized. Transfer functions other than logarithm or inverse logarithm are also possible, and any appropriate mathematical function may be utilized, particularly those that have a complementary or reversible characteristic.

Furthermore, a transfer function can also be stored in the form of a value table. The transfer function is preferably adjustable and can be varied by programming of the appertaining hearing aid. Given, thus, a transducer with a compressing transmission characteristic (transducer characteristic), this can be measured and the characteristic that is exactly inverse to it can be set at the expander.

The invention can be applied to all known hearing aid types, for example hearing aids to be worn behind the ear, hearing aids to be worn in the ear, implantable hearing aids or pocket hearing aids. Further, the hearing aid of the invention can also be part of a hearing aid system comprising a plurality of devices for supplying a hearing-impaired person, for example part of a hearing aid system having two hearing aids worn at the head or part of a hearing aid system composed of a hearing aid worn at the head and a processor unit carried on the body.

### DESCRIPTION OF THE DRAWINGS

Further details of the invention are explained in greater detail below on the basis of exemplary embodiments and the drawings.

FIG. 1 is a schematic block circuit diagram of a hearing aid with an HLC of the Prior Art;

FIG. 2 is a graph showing the transmission characteristic of an HLC in a simplified illustration;

FIG. 3 is a schematic block circuit diagram of a hearing aid of the invention;

FIG. 4 is a graph showing the transmission characteristic of the compression unit; and

FIG. 5 is a graph showing the transmission characteristic of the expansion unit.

### DETAILED DESCRIPTION OF THE INVENTION

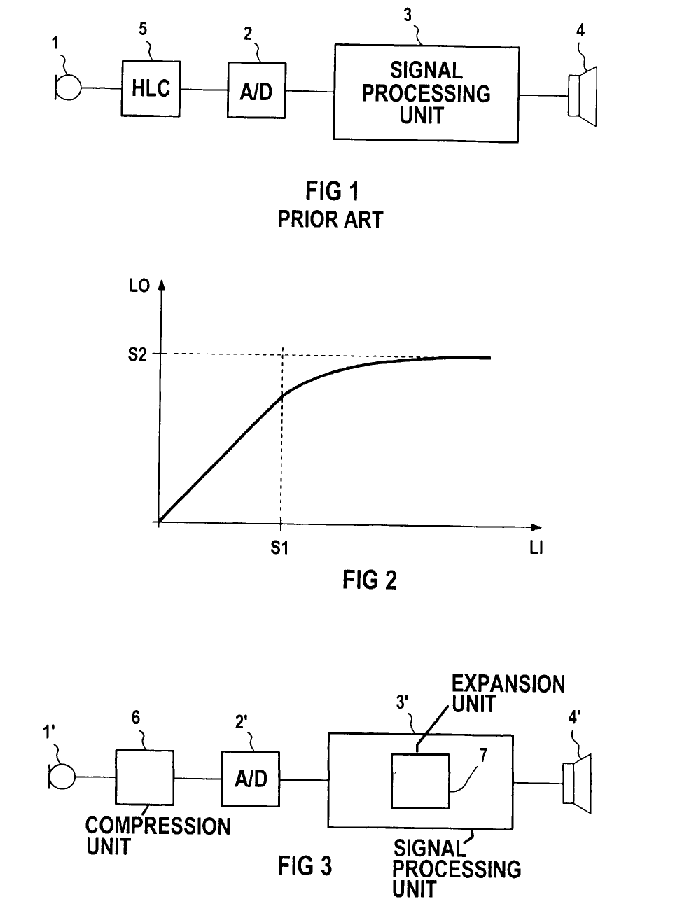

FIG. 1 shows a schematic illustration of the block circuit diagram of a hearing aid with an input transducer fashioned as microphone 1. This picks up an acoustic input signal and converts it into an electrical signal. The dynamic range of the microphone 1, i.e., the range from the lowest to the highest signal amplitude of the input signal that can be transmitted, is usually significantly greater than the dynamic range that the hearing aid offers overall.

In the known hearing aid, an A/D converter 2 is provided for converting the electrical signal into a digital signal. The digital signal is supplied to a signal processing unit 3 in which the editing of the signal ensues for compensating the individual hearing impairment of the hearing aid user. The signal processing can be implemented in a plurality of parallel channels of the signal processing unit 3 and can also comprise further functions such as unwanted noise suppression or special emphasis of voice signals in addition to a frequency-dependent amplification. The processed signal is finally converted from an electrical signal into an acoustic signal by the output transducer, realized as an earphone in the example, and is output.

The dynamic range of the signal that can be transmitted with the hearing aid is essentially defined by the A/D converter. An expansion of the dynamic range could be supported in the signal processing unit 3 using an expansion of the word width of the digital signal to be processed. The power consumption of the signal processing unit 3 varies roughly proportional to the selected word width. This differs in comparison with the A/D converter 2 in which an increase in the dynamic range results from a higher supply voltage and, thus, in a disproportional increase in the power consumption.

Due to the desired miniaturization in hearing aids, the space that is available within the hearing aid for the battery or the accumulator for the voltage supply is limited, as is, thus, the output voltage and storage capacity thereof. The realizable dynamic range of the A/D converter 2 is prescribed within narrow limits in the development of a hearing aid. In order to avoid an overdrive/overload of the A/D converter 2 given high signal amplitudes of the input signal, the hearing aid according to FIG. 1 provides an HLC 5 connected between the microphone 1 and the A/D converter 2. This is constructed in analog circuit technology and—above a specific threshold S1 (see FIG. 2) of the signal amplitude of the input signal—effects a compression of the input signal before it is supplied to the A/D converter 2. This HLC 5 is only activated when the signal amplitude exceeds the threshold S1 for a specific time duration. Likewise, the circuit is in turn deactivated only when the signal amplitude falls below the threshold S1 for a specific time duration. The HLC 5 is a regulating circuit and thus exhibits a response or decay time. As a result, its response causes a modification of the original input signal that is clearly audible and disturbing for the hearing aid user.

In a simplified illustration, FIG. 2 shows the transmission characteristic of the HLC 5 for the respectively steady state. The output signal level LO is shown over the input signal level LI of the HLC 5. The threshold S1 at which the regulation sets in and the HLC 5 becomes active is also shown. Below S1, the characteristic proceeds linearly with the slope 1. Above S1, the transmission characteristic for the steady state of the regulator approaches the threshold S2 with increasing input signal level.

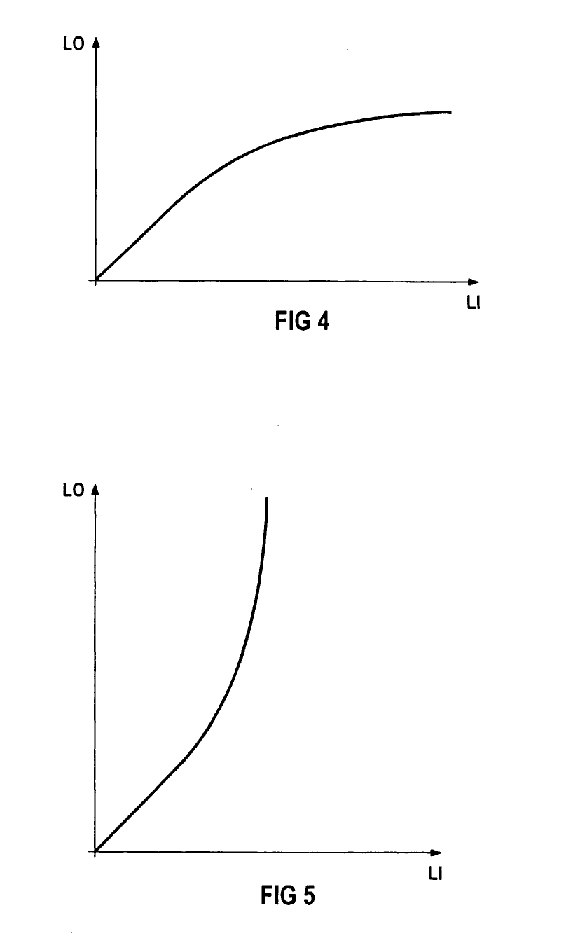

FIG. 3 shows a schematic illustration of the block circuit diagram of a hearing aid of the invention. This also provides a microphone 1′, an A/D converter 2′, a signal processing unit 3′ as well as an earphone 4′. The inventive hearing aid differs from the Prior Art, in that it always compresses the analog input signal before it is supplied to the A/D converter 2′ (and not only above a specific threshold) with a compression unit 6 based on the criterion of a compression characteristic. The compression ratio can also be equal to one in a specific value range of the input signal level. The compression unit 6 is implemented in analog circuit technology and realizes a control with the transmission characteristic shown in FIG. 4. The inventive compression unit 6 differs from the HLC 5 according to FIG. 1 because the compression unit 6 does not have a threshold in view of the signal amplitude of the input signal that must be exceeded so that the circuit is activated. On the contrary, the adaptation of the analog input signal ensues directly, permanently and continuously. The compression unit 6 is not a regulating circuit and also does not exhibit any response or decay times.

Advantageously, the compression unit 6 is fashioned as an analog logarithmizer in terms of circuit technology (see, e.g., Tietze, U., Schenk, C H, Halbleiter-Schaltungstechnik, Berlin, Heidelberg, New York, London, Paris, Tokyo, Barcelona: Springer 1990, herein incorporated by reference) and can also effect a signal pre-amplification at the same time. Furthermore, the compression unit 6 can be implemented as an autonomous circuit unit in the hearing aid but can also be integrated into the microphone 1′ or the A/D converter 2′.

The hearing aid according to FIG. 3 also comprises an expansion unit 7. This is integrated in the signal processing unit 3′ and may be realized in digital circuit technology. The expansion unit 7 serves for expanding the signal compressed in the compression unit 6. A further signal processing can ensue in the signal processing unit both before as well as after the expansion. Overall, the hearing aid fashioned in this way exhibits a dynamic range that clearly exceeds the dynamic range of the A/D converter 2′.

The transmission characteristic of the compression unit 6 is executed as function of the output signal level LO over the input signal level LI in FIG. 4. This also at least approximately exhibits a linear curve with a slope one given low signal levels and gradually flattens toward higher input signal levels. The transmission characteristic can be roughly described by a logarithm function in the value range of interest in the input signal level, but, as noted above, any appropriate mathematical function (preferably one with a reversible or complementary counterpart) may be utilized. More than one function and complementing function pair may be utilized based on a frequency channel, i.e., different frequency bands and associated processing of those frequency bands may utilize different function pairs in order to optimize the processing.

FIG. 5 shows the expansion characteristic realized by the expansion unit 7, this being the inverse of the compression characteristic according to FIG. 4. Based on the criterion of this expansion characteristic, the compression of the input signal that ensued in the compression unit 6 is at least approximately cancelled in the expansion unit 7. This results in the hearing aid fashioned in this way exhibiting a broader dynamic range than would be enabled by the A/D converter 2′ without the further circuitry according to the invention.

Differing from the illustrated exemplary embodiment according to FIG. 3 that comprises the compression unit 6, a compressed signal transmission behavior according to FIG. 4 can also be directly effected by the microphone 1′. For this purpose, the microphone 1′ comprises an acousto-mechanical compression part (not shown). The effect of this can, for example, be based on a specific fashioning of the microphone membrane (membrane regions differing in thickness).

The expansion unit 7 is preferably programmably fashioned for realizing the inverse transmission characteristic of the hearing aid. The exact curve of the transmission characteristic can then be varied by programming the hearing aid,

For the purposes of promoting an understanding of the principles of the invention, reference has been made to the preferred embodiments illustrated in the drawings, and specific language has been used to describe these embodiments. However, no limitation of the scope of the invention is intended by this specific language, and the invention should be construed to encompass all embodiments that would normally occur to one of ordinary skill in the art.

The present invention may be described in terms of functional block components and various processing steps. Such functional blocks may be realized by any number of hardware and/or software components configured to perform the specified functions. For example, the present invention may employ various integrated circuit components, e.g., memory elements, processing elements, logic elements, look-up tables, and the like, which may carry out a variety of functions under the control of one or more microprocessors or other control devices. Similarly, where the elements of the present invention are implemented using software programming or software elements the invention may be implemented with any programming or scripting language such as C, C++, Java, assembler, or the like, with the various algorithms being implemented with any combination of data structures, objects, processes, routines or other programming elements. Furthermore, the present invention could employ any number of conventional techniques for electronics configuration, signal processing and/or control, data processing and the like.

The particular implementations shown and described herein are illustrative examples of the invention and are not intended to otherwise limit the scope of the invention in any way. For the sake of brevity, conventional electronics, control systems, software development and other functional aspects of the systems (and components of the individual operating components of the systems) may not be described in detail. Furthermore, the connecting lines, or connectors shown in the various figures presented are intended to represent exemplary functional relationships and/or physical or logical couplings between the various elements. It should be noted that many alternative or additional functional relationships, physical connections or logical connections may be present in a practical device. Moreover, no item or component is essential to the practice of the invention unless the element is specifically described as “essential” or “critical”. Numerous modifications and adaptations will be readily apparent to those skilled in this art without departing from the spirit and scope of the present invention.

List of Reference Characters

1, 1′ microphone

2, 2′ A/D converter

3, 3′ signal processing unit

4, 4′ earphone

5 HLC

6 compression unit

7 expansion unit

S1, S2 thresholds

What is claimed is:

1. A method for operating a hearing aid, comprising:
receiving an input signal via at least one input transducer and converting it into an electrical signal;
compressing the electrical signal based on a compression characteristic criterion, thus producing a compressed electrical signal;
converting the compressed electrical signal into a compressed digital signal with an A/D converter;
processing the compressed digital signal with a signal processing unit;
expanding the compressed digital signal before or after processing based on an expansion characteristic that is at least substantially inversely related to the compression characteristic.

2. The method according to claim 1, wherein the compression characteristic criterion is substantially a logarithmic function and the expansion characteristic criterion is substantially an inverse logarithmic function.

3. A hearing aid, comprising:
an input transducer configured to receive an input signal and convert it to an electrical signal, the input transducer configured to implement a compression characteristic on the electrical signal;
an A/D converter connected to the input transducer and configured to convert the compressed electrical signal into a compressed digital signal;
a signal processing unit connected to the A/D converter configured to process the compressed digital signal, thus creating a processed signal; and
an output transducer for converting the processed signal into an output signal.

4. The hearing aid according to claim 3, further comprising:
a compression adjustment mechanism configured to adjust the compression characteristic.

5. The hearing aid according to claim 3, further comprising:
an expansion unit connected to the output transducer and configured to receive a compressed digital signal and expand it.

6. The hearing aid according to claim 3, further comprising:
a transducer membrane of the input transducer that differs in thickness.

7. The hearing aid according to claim 5, further comprising:
an expansion adjustment mechanism configured to adjust the expansion characteristic.

8. A hearing aid, comprising:
an input transducer configured to receive an input signal and convert it to an electrical signal;
a compression unit connected to the input transducer and configured to compress the electrical signal into a compressed signal;
an A/D converter connected to the compression unit and configured to receive the compressed signal and to convert it into a compressed digital signal;
a signal processing unit connected to the A/D converter configured to process the compressed digital signal, thus creating a processed signal; and
an output transducer for converting the processed signal into an output signal.

9. The hearing aid according to claim 8, further comprising:
an expansion unit connected to the output transducer and configured to receive a compressed digital signal and expand it.

10. The hearing aid according to claim 8, wherein the compression unit is a continuously active compression unit configured to operate independent of an input signal level.
